(19) United States
(12) Patent Application Publication
(10) Pub. No.: US 2017/0069582 A1
(43) Pub. Date: Mar. 9, 2017

(54) SEMICONDUCTOR DEVICE INCLUDING PASSIVE EQUALIZER CIRCUIT

(71) Applicant: Samsung Electronics Co., Ltd., Suwon-si (KR)

(72) Inventors: Il-Joon KIM, Seoul (KR); SunWon KANG, Seongnam-si (KR)

(21) Appl. No.: 15/172,917

(22) Filed: Jun. 3, 2016

(30) Foreign Application Priority Data
Sep. 9, 2015 (KR) 10-2015-0127751

(51) Int. Cl. H01L 23/64; H01L 27/108; H01L 23/00; H01L 25/065; H01L 23/522; H01L 23/498

(52) U.S. Cl. CPC H01L 23/642; H01L 23/5223; H01L 23/49811; H01L 24/48; H01L 23/5226; H01L 24/02; H01L 25/0657; H01L 27/10897; H01L 2224/48091; H01L 2224/48105; H01L 2224/48228; H01L 2224/48111; H01L 2924/1434; H01L 2224/02331; H01L 2225/06562; H01L 2225/0651; H01L 2924/1436

(57) ABSTRACT

A semiconductor device includes a first set of pads disposed at a first vertical level on a substrate, a first interconnection layer formed at a second vertical level higher than the first vertical level on the substrate, a second interconnection layer formed at a third vertical level higher than the second vertical level on the substrate, capacitive elements included in either the first or the second interconnection layer, and a second set of pads disposed at a fourth vertical level higher than the third vertical level on the substrate. A first capacitive element of the capacitive elements is connected between a first portion and a second portion of the first interconnection layer or a first capacitive element of the capacitive elements is connected between a third portion and a fourth portion of the second interconnection layer.

### CROSS-REFERENCE TO RELATED APPLICATIONS

This US non-provisional patent application claims priority under 35 USC §119 to Korean Patent Application No. 10-2015-0127751, filed on Sep. 9, 2015, the entirety of which is hereby incorporated by reference.

### BACKGROUND

The present disclosure relates to semiconductor devices and, more particularly, to a semiconductor device including a passive equalizer circuit.

Semiconductor devices have been used in various electronic industries due to their characteristics such as miniaturization, multi-functionality, and/or low manufacturing cost. Semiconductor devices may include a memory element to store data, a logic element to process data, and a hybrid element capable of performing various functions.

As the electronic industry continues to grow at a rapid pace, use of portable electronic devices has become extremely popular. Power durability of these portable electronic devices is typically very important to achieve their portability. Accordingly, a semiconductor device for use in these portable electronic devices generally needs to operate at a low power. Currently, a low-power DRAM (LPDRAM) is widely being used as a working memory of a portable electronic device. Since such a low-power DRAM operates at a low power, the signal integrity of a transmission signal may be degraded by an impedance element of a signal transmission line.

### SUMMARY

The present disclosure relates to a semiconductor device with improved signal integrity.

According to example embodiments, a semiconductor device includes a first set of pads disposed at a first vertical level on a substrate, a first interconnection layer formed at a second vertical level higher than the first vertical level on the substrate, the first interconnection layer including a first set of interconnections, a second interconnection layer formed at a third vertical level higher than the second vertical level on the substrate, the second interconnection layer including a second set of interconnections, capacitive elements included in either the first or the second interconnection layer, and a second set of pads disposed at a fourth vertical level higher than the third vertical level on the substrate. A first interconnection of the first set of interconnections and a second interconnection of the second set of interconnections are electrically connected to a first pad of the first set of pads and a second pad of the second set of pads. A first capacitive element of the capacitive elements is connected between a first portion and a second portion spaced apart from the first portion of the first interconnection, or a first capacitive element of the capacitive elements is connected between a third portion and a fourth portion spaced apart from the third portion of the second interconnection.

In example embodiments, each of the capacitive elements may be a capacitor, and the capacitor includes a dielectric material having a high-k constant.

In example embodiments, the capacitor may be an embedded capacitor embedded in the first interconnection layer.

In example embodiments, the first set of pads connected to the capacitive elements may be pads to which transmission signals are transmitted.

In example embodiments, the first set of pads may be disposed in a first direction at a central portion of the top surface of the substrate.

In example embodiments, the substrate is included in a memory chip, and the semiconductor device may further include a printed circuit board mounted on a bottom of the memory chip. The printed circuit board may have a top surface at which a third set of pads are disposed.

In example embodiments, each pad of the second set of pads and each pad of the third set of pads may be connected each other through a bonding wire.

In example embodiments, the memory chip may be a low-power random access memory.

According to example embodiments, a semiconductor device includes a substrate, a first set of pads disposed at a central portion of the substrate, the first set of pads arranged in a first direction or a second direction perpendicular to the first direction, a second set of pads disposed at a first edge portion of the substrate, the second set of pads arranged in the first direction or the second direction, a first interconnection layer formed at a first vertical level on the substrate, the first interconnection layer in which includes a first set of interconnections each electrically connected to a corresponding pad of the first set of pads, a second interconnection layer formed at a second vertical level higher than the first vertical level on the substrate, the second interconnection layer including a second set of interconnections each electrically connected between a corresponding interconnection of the first set of interconnections and a corresponding pad of the second set of pads, capacitors included in either the first interconnection layer or the second interconnection layer. The capacitors are connected between a first portion of each interconnection of the first set of interconnections and a second portion of each interconnection of the first set of interconnections, respectively, or the capacitors are connected between a third portion of each interconnection of the second set of interconnections and a fourth portion of each interconnection of the second set of interconnections, respectively.

In example embodiments, the substrate is included in a memory chip, each of the capacitors may be connected to a corresponding interconnection, which is a signal transmission line through which a signal of the memory chip is transmitted.

According to example embodiments, a semiconductor device includes a substrate, first through third vias, a first pad disposed at a first vertical level at a central portion of the substrate, a first interconnection layer formed at a second vertical level higher than the first vertical level on the substrate, and electrically connected to the first pad through the first via, a second interconnection layer formed at a third vertical level higher than the second vertical level on the substrate, and electrically connected to the first interconnection layer through the second via, a second pad disposed at a fourth vertical level higher than the third vertical level on the substrate at a first edge portion of the substrate, and electrically connected to the second interconnection layer through the third via, and a capacitive element is electrically connected between a first portion and a second portion of the first interconnection layer at a second edge portion of the substrate opposite to the first edge portion, or a capacitive element electrically connected between a third portion and a fourth portion of the second interconnection layer.

### BRIEF DESCRIPTION OF THE DRAWINGS

The forgoing and other features of inventive concepts will be described below in more detail with reference to the accompanying drawings of non-limiting embodiments of inventive concepts in which like reference characters refer to like parts throughout the different views. The drawings are not necessarily to scale, emphasis instead being placed upon illustrating principles of inventive concepts. In the drawings:

FIG. 1A is a cross-sectional view of a semiconductor device according to example embodiments;

FIG. 1B is a cross-sectional view of a semiconductor device according to example embodiments;

FIG. 2A is a top plan view of a memory chip in the semiconductor device in FIG. 1A or 1B according to example embodiments;

FIG. 2B is a top plan view of a first interconnection layer in the semiconductor device in FIG. 1A or 1B according to example embodiments;

FIG. 2C is a top plan view of a second interconnection layer in the semiconductor device in FIG. 1A or 1B according to example embodiments;

FIG. 3 is an equivalent circuit diagram between a certain pad of a semiconductor chip and an external pad to electrically connect the pad to an interconnection layer according to example embodiments;

FIG. 4 is a cross-sectional view of a semiconductor device according to example embodiments;

FIG. 5 is an equivalent circuit diagram of a memory chip and interconnection layers of the semiconductor device according to FIG. 4 according to example embodiments;

FIG. 6 is a cross-sectional view of a semiconductor device according to example embodiments; and

FIG. 7 is an equivalent circuit diagram of a memory chip and interconnection layers of a semiconductor device according to FIG. 6 according to example embodiments.

### DETAILED DESCRIPTION

Example embodiments will now be described more fully with reference to the accompanying drawings, in which some example embodiments are shown. Example embodiments may, however, be embodied in many different forms and should not be construed as being limited to the embodiments set forth herein. In the drawings, the thicknesses of layers and regions are exaggerated for clarity. Like reference characters and/or numerals in the drawings denote like elements, and thus their description may be omitted.

It will be understood that, although the terms first, second, third etc. may be used herein to describe various elements, these elements should not be limited by these terms. Unless indicated otherwise, these terms are used to distinguish one element from another. Thus, a first element discussed below could be termed a second element without departing from the teachings of the present disclosure. As used herein, the term “and/or” includes any and all combinations of one or more of the associated listed items. Expressions such as “at least one of,” when preceding a list of elements, modify the entire list of elements and do not modify the individual elements of the list.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. The term “contacting” refers to a direct connection (i.e., touching), unless the context indicates otherwise. Other words used to describe the relationship between elements should be interpreted in a like fashion (e.g., “between” versus “directly between,” “adjacent” versus “directly adjacent,” etc.).

The terminology used herein is for the purpose of describing particular example embodiments only and is not intended to be limiting of the present disclosure. As used herein, the singular forms “a,” “an” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Unless the context indicates otherwise, terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to reflect this meaning. For example, items described as “substantially the same,” “substantially equal,” or “substantially planar,” may be exactly the same, equal, or planar, or may be the same, equal, or planar within acceptable variations that may occur, for example, due to manufacturing processes.

As used herein, items described as being “electrically connected” are configured such that an electrical signal can be passed from one item to the other. Therefore, a passive electrically conductive component (e.g., a wire, pad, internal electrical line, etc.) physically connected to a passive electrically insulative component (e.g., a prepreg layer of a printed circuit board, an electrically insulative adhesive connecting two device, an electrically insulative underfill or mold layer, etc.) is not electrically connected to that component. Moreover, items that are “directly electrically connected,” to each other are electrically connected through one or more passive elements, such as, for example, wires, pads, internal electrical lines, through vias, etc. As such, directly electrically connected components do not include components electrically connected through active elements, such as transistors or diodes. Directly electrically connected elements may be directly physically connected and directly electrically connected.

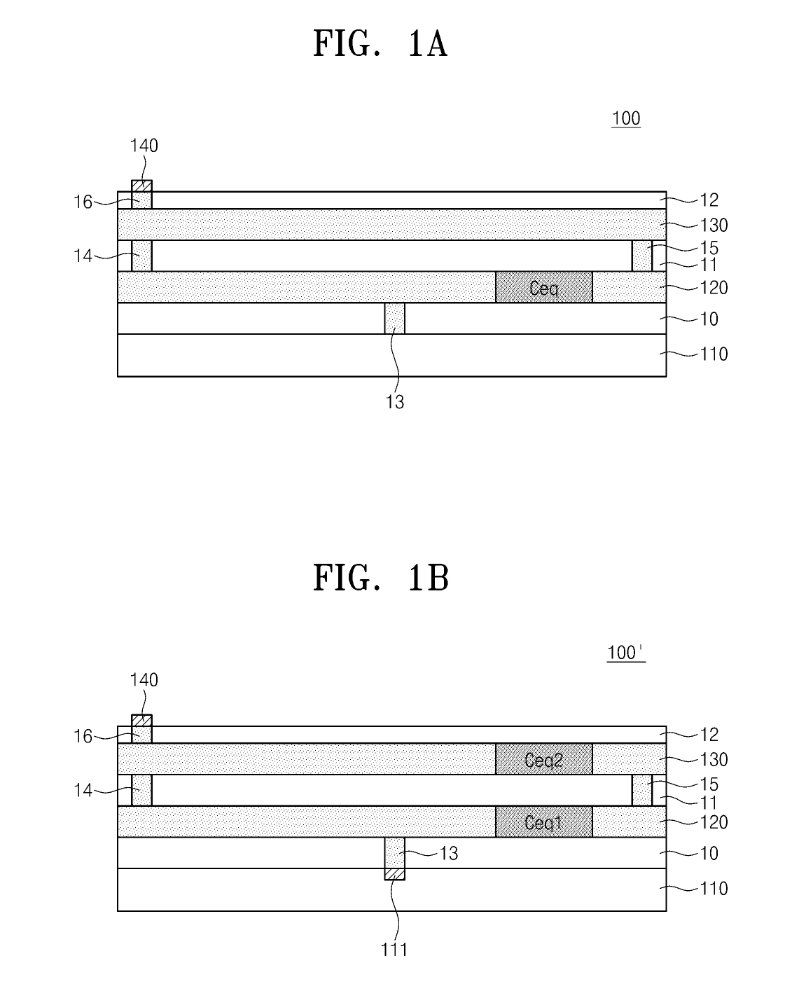

FIG. 1A is a cross-sectional view of a semiconductor device 100 according to example embodiments. As illustrated, the semiconductor device 100 may include a memory chip 110, a first interconnection layer 120, a second interconnection layer 130, edge pads 140, first to third insulating layers 10, 11, and 12, and first to fourth vias 13, 14, 15, and 16. A capacitor Ceq may be formed in one region of the first interconnection layer 120. Hereinafter, the semiconductor device 100 will be described in detail with reference to FIG. 1A.

In example embodiments, the memory chip 110 may include a semiconductor substrate on which a plurality of circuits and a memory cell array having a plurality of memory cells are disposed. In one embodiment, the memory chip 110 may also include the first interconnection layer 120, the second interconnection layer 130, the edge pads 140, the first to third insulating layers 10, 11, and 12, and the first to fourth vias 13, 14, 15, and 16.

As used herein, a semiconductor device may refer to any of the various devices such as shown in FIGS. 1A, 1B, 2A-2C, 4, and 6, and may also refer, for example, to a device such as a semiconductor chip (e.g., memory chip and/or logic chip formed from a wafer), a stack of semiconductor chips, a semiconductor package including one or more semiconductor chips stacked on a package substrate, or a package-on-package device including a plurality of packages.

The memory chip 110 may be a volatile memory chip. For example, the memory chip 110 may be a dynamic random access memory (DRAM). For example, the memory chip 110 may be a low-power DRAM (LPDRAM). In a center of a top surface of the memory chip 110, for example, center pads (not shown) may be disposed in a first direction or a second direction different from the first direction. The first direction and the second direction disclosed herein may be directions parallel to an edge of the memory chip 100, and may be, for example, perpendicular to each other.

The center of the substrate or the center of the memory chip disclosed herein may include a central portion or middle portion of the memory chip, when viewed from a plan view. As one example, a central portion or middle portion of the memory chip may include a central one-third portion of the memory chip.

The edge pads may refer to pads disposed at an edge portion of the substrate and the center pads may be referred to pads disposed at a central portion of the substrate. The edge portion may include, for example, a portion of the substrate adjacent to the edge of the substrate.

The first insulating layer 10 may be disposed on the memory chip 110. The first insulating layer 10 electrically insulates the memory chip 110 from the first interconnection layer 120.

The first interconnection layer 120 may be disposed on the first insulating layer 10. The first interconnection layer 120 may be formed at a first vertical level on a top surface of the memory chip 100. In example embodiments, the first interconnection layer 120 may include a plurality of interconnections and a plurality of capacitors. The respective interconnections of the first interconnection layer 120 and a corresponding pad of the center pads of the memory chip 110 may be electrically connected to each other through a first via 13 penetrating the first insulating layer 10. The capacitor Ceq may be disposed in the first interconnection layer 120 in an embedded form. For example, the capacitor Ceq may be an embedded capacitor. A first end of the capacitor Ceq is electrically connected to one of the center pads of the memory chip 110 through an interconnection of the first interconnection layer 120 and the first via 13. A second end of the capacitor Ceq may be connected to one of the edge pads 140 through an interconnection of the second interconnection layer 130. In example embodiments, for example, the capacitor Ceq may include a dielectric material. The dielectric material of the capacitor Ceq may have a higher dielectric constant k than a dielectric material of each of the first through third insulating layers 10, 11, and 12. A certain interconnection of the first interconnection layer 120 may be electrically connected to a corresponding pad of the edge pads 140 through the second via 14 penetrating the second insulating layer 11 and the fourth via 16 penetrating the third insulating layer 12.

The second insulating layer 11 may be disposed on the first interconnection layer 120. The second insulating layer 11 electrically insulates the first interconnection layer 120 from the second interconnection layer 130.

The second interconnection layer 130 may be disposed on the second insulating layer 11. The second interconnection layer 130 may be formed at a second vertical level on the second insulating layer 11. In example embodiments, the second interconnection layer 130 may include a plurality of interconnections. Each of the respective interconnections of the second interconnection layer 130 is electrically connected to a capacitor Ceq disposed in the first interconnection layer 120 through a third via 15 penetrating the second insulating layer 11. Each interconnection of the second interconnection layer 130 is electrically connected to a corresponding pad of the edge pads 140 through the fourth via 16 penetrating the third insulating layer 12.

The third insulating layer 12 is disposed on the second interconnection layer 130 to electrically insulate the interconnections of the second interconnection layer 130 from an external entity.

In the above-described semiconductor memory device 100, capacitors Ceq are coupled in parallel between some of the center pads of the memory chip 100 and some of the edge pads 133, respectively. The capacitor Ceq coupled in parallel is connected to some pads, among the center pads, where a signal is transmitted/received to/from the memory chip 110. The coupled capacitor Ceq may change a resonant frequency of an equivalent circuit between a center pad and an edge pad of the memory chip 110. A gain of an output signal depending on the changed resonant frequency may increase. Thus, the output signal may be equalized through the edge pad. As a result, the signal integrity of the output signal may be improved.

FIG. 1B is a cross-sectional view of a semiconductor device 100′ according to example embodiments. In example embodiments, detailed descriptions of the same contents as those of the above-described embodiments in FIG. 1A may be omitted.

Referring to FIG. 1B, the semiconductor device 100′ shows a center pad 111. A first capacitor Ceq1 may be formed in one region of the first interconnection layer 120 and a second capacitor Ceq2 may be formed in one region of the second interconnection layer 130. In example embodiments, at least one of the first capacitor Ceq1 or the second capacitor Ceq2 are formed (e.g., only Ceq1 may be formed, only Ceq2 may be formed, or both Ceq1 and Ceq2 may be formed). In example embodiments, the second capacitor Ceq2 may include a dielectric material. For example, the dielectric material of the second capacitor Ceq2 may be formed between a first portion and a second portion of the second interconnection layer 130. The dielectric material of the second capacitor Ceq2 has a higher dielectric constant k than a dielectric material of each of the first through third insulating layers 10, 11, and 12. In other example embodiments, the second capacitor Ceq2 may include a capacitor component. In this case, the semiconductor device 100′ may further include fifth and sixth vias (not shown) penetrating the third insulating layer 12, and include first and second conductive pads (not shown) directly connected to the fifth and sixth vias, respectively. The fifth via is electrically connected between a first portion of the second interconnection layer 130 and the first conductive pad, and the sixth via is electrically connected between a second portion of the second interconnection layer 130 and the second conductive pad. Thus, the capacitor component of the second capacitor Ceq2 may be disposed on the third insulating layer 12 (e.g., rather than being embedded in the second interconnection layer 130) and may be directly connected between the first and second conductive pads (e.g., it can be a separate capacitor connected between two pads at the top of the third insulating layer 12).

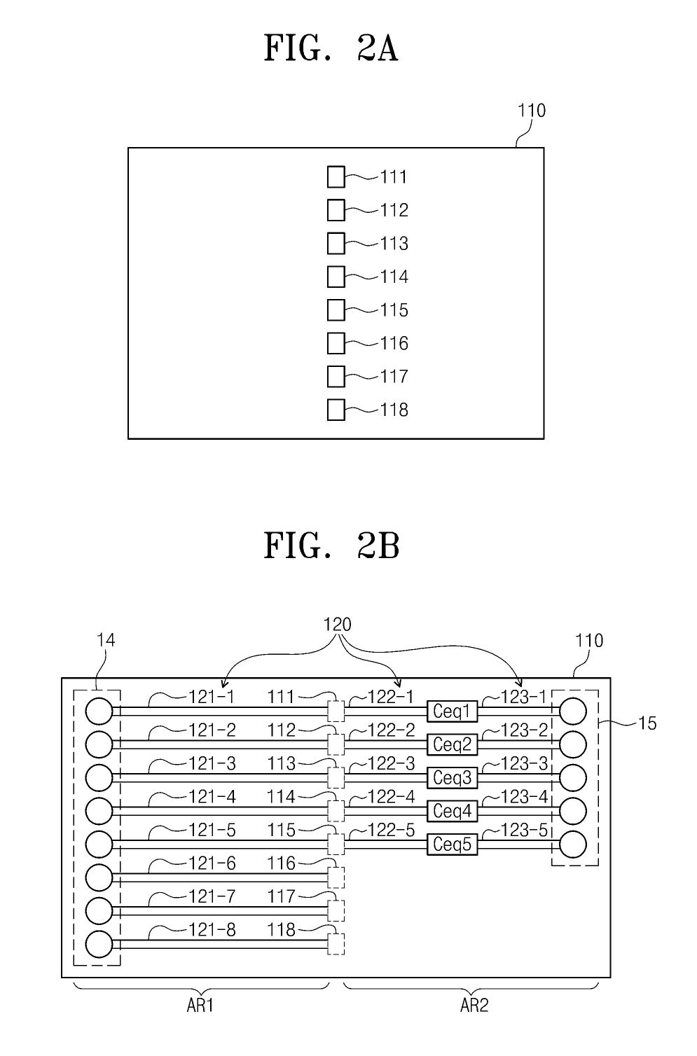

FIG. 2A is a top plan view of the memory chip 110 in the semiconductor device 100 in FIG. 1A or 1B according to example embodiments. As illustrated, the memory chip 110 may include first to eighth center pads 111 to 118 disposed in the center of the memory chip 110 in a first direction (e.g., column direction). Alternatively, the first to eighth center pads 111 to 118 may be disposed in the center of the memory chip 110 in a second direction (e.g., row direction). The number of the center pads 111 to 118 is merely exemplary and may vary depending on type and purpose of a memory chip.

Some of the first to eighth center pads 111 to 118 may be power pad to which power is input, and others may be signal pads to which a signal is input/output. The capacitors Ceq may be connected for equalizing an output signal to the signal pads.

FIG. 2B is a top plan view of the first interconnection layer 120 in the semiconductor device in FIG. 1A or 1B according to example embodiments. As illustrated, the first interconnection layer 120 may include a plurality of first interconnections 121-1 to 121-8, 122-1 to 122-5, and 123-1 to 123-5 and a plurality of capacitors Ceq1 to Ceq5.

First ends of the first interconnections 121-1 to 121-8 are electrically connected to the center pads 111 to 118 of the memory chip 110 through first vias 13 (not shown), respectively. Second ends of the first interconnections 121-1 to 121-8 are directly connected to second vias 14, respectively.

First ends of the capacitors Ceq1 to Ceq5 are connected to the first to fifth pads 111 to 115, which are some of the center pads 111 to 118 of the memory chip 110, through the first vias 13 (not shown) and the first interconnections 122-1 to 122-5, respectively. Second ends of the capacitors Ceq1 to Ceq5 are connected to third vias 15 and the first interconnections 123-1 to 123-5, respectively.

The first interconnections 121-1 to 121-8 are formed in a first region AR1 of the memory chip 110, and the capacitors Ceq1 to Ceq5 are formed in a second region AR2 of the memory chip 110. That is, the first interconnections 121-1 to 121-5 and the capacitors Ceq1 to Ceq5 are formed to be spatially apart from the center pads 111 to 115.

FIG. 2C is a top plan view of the second interconnection layer 130 in the semiconductor device in FIG. 1A or 1B according to example embodiments. As illustrated, the second interconnection layer 130 may include a plurality of second interconnections 131-1 to 131-5.

First ends of the second interconnections 131-1 to 131-5 are electrically connected to the second ends of the capacitors Ceq1 to Ceq5 disposed in the first interconnection layer 120 through each of third vias 15 and the first interconnections 123-1 to 123-5, respectively. Second ends of the second interconnections 131-1 to 131-5 are directly connected to some of fourth vias 16, respectively. The fourth vias 16 are electrically and directly connected to edge pads 140. Thus, the second interconnections 131-1 to 131-5 are electrically connected to the edge pads 140 through the fourth vias 16.

As described with reference to FIGS. 2A to 2C, the capacitors Ceq1 to Ceq5 disposed in the first interconnection layer 110 are connected in parallel to some of the center pads of the memory chip 110 and some of the edge pads 140. In this case, the pads connected to the capacitors Ceq1 to Ceq5 may be signal pads where a signal is output from the memory chip 110 or signal pads where a signal is transmitted to the memory chip 110 from an external entity. Center pads may be arranged in a first direction, and edge pads connected to the center pads may be arranged in a second direction that may be the same direction as the first direction (e.g., as shown in FIG. 2B), or may be a different (e.g., perpendicular) direction. Signals output through signal transmission lines may by equalized by charge-discharge effect of the capacitors Cequ1 to Ceq5. Thus, the signal integrity of the output signals may be improved.

In example embodiments, each of the first interconnection layer 120 and the second interconnection layer 130 may be a redistribution conductive layer. For example, the redistribution conductive layer may be used for packaging the semiconductor device, such as to allow the semiconductor device to connect to a package substrate.

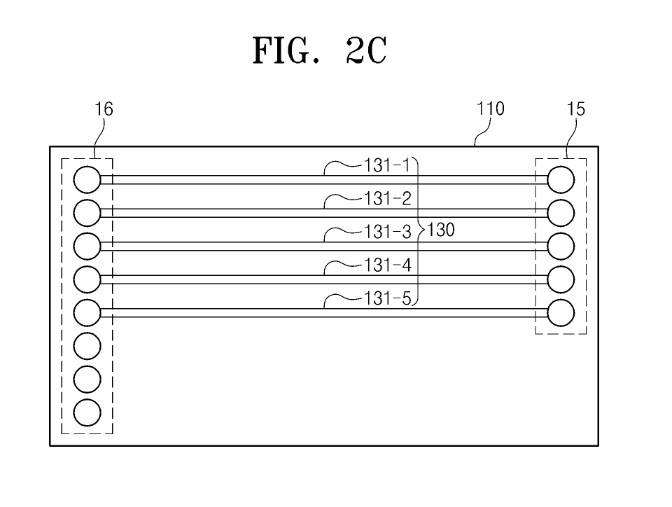

FIG. 3 is an equivalent circuit diagram between a center pad and an edge pad electrically connected to each other through the first and second interconnection layers according to example embodiments. As illustrated, an equivalent circuit between a center pad PD_MC and an edge pad PD_EG of a memory chip includes an interconnection resistor Rdl to equalize a resistance element of an interconnection, an interconnection inductor Ldl to equalize an inductance element of the interconnection, an interconnection capacitor Cdl to equalize a capacitance element of the interconnection, and a capacitor Ceq connected between the center pad PD_MC and the edge pad PD_EG.

The capacitor Ceq connected between the center pad PD_MC and the edge pad PD_EG may change a resonant frequency of the equivalent circuit, as compared to a case where the capacitor Ceq does not exist. The changed resonant frequency may increase a gain of a signal output through the edge pad PD_EG. In the stage of design, capacitance of the capacitor Ceq may be suitably set to increase the gain of the signal output through the edge pad PD_EG.

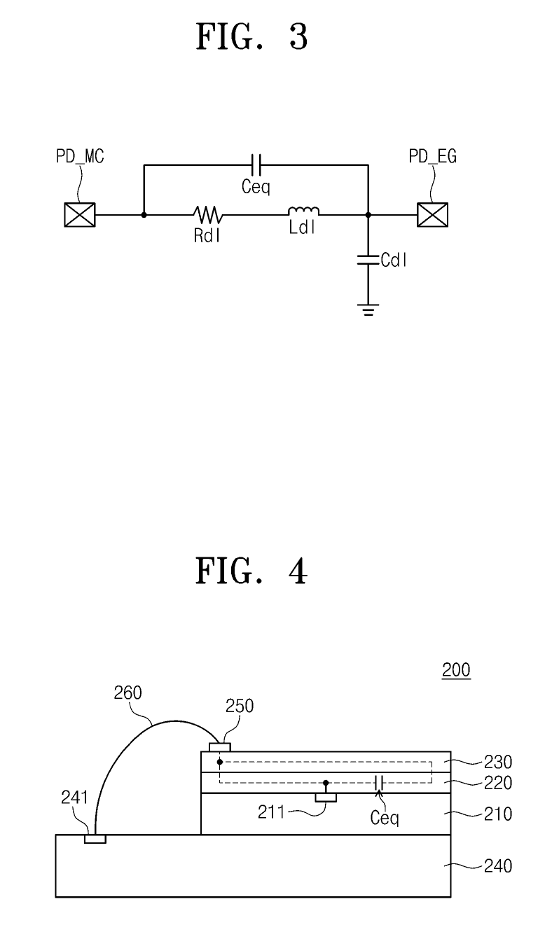

FIG. 4 is a cross-sectional view of a semiconductor device 200 according to example embodiments. As illustrated, the semiconductor device 200 may include a memory chip 210, a first interconnection layer 220, a second interconnection layer 230, and a printed circuit board (PCB) 240. Insulating layers and vias in FIG. 4 will be omitted for the purpose of ease and convenience in explanation. In one embodiment, the memory chip 210 may include a plurality of circuits (not shown), the first interconnection layer 220 and the second interconnection layer 230. The semiconductor device 200 may include a capacitor Ceq disposed in the first interconnection layer 220. Alternatively, the semiconductor device 200 may include a capacitor Ceq embedded in the second interconnection layer 230.

The memory chip 210 includes a center pad 211 and receives/transmits a signal from/to an external device through the center pad 211. The center pad 211 is electrically connected to an edge pad 250 through an interconnection disposed in the first interconnection layer 220 indicated by a dotted line. The memory chip 210 may include the first interconnection layer 220, the second interconnection layer 230, and the edge pad 250.

The capacitor Ceq is disposed in the first interconnection layer 220. The capacitor Ceq is embedded to be formed in the first interconnection layer 220. For example, the capacitor Ceq may be formed by placing two metal materials (e.g., copper) with a space therebetween. A first end of the capacitor Ceq is electrically connected to the center pad 211 of the memory chip 210, and a second end of the capacitor Ceq is electrically connected to the edge pad 250 through an interconnection disposed in the second interconnection layer 230. For example, the capacitor Ceq is connected in parallel to a signal transmission line between the center pad 211 and the edge pad 250.

A second interconnection indicated by a dotted line is disposed in the second interconnection layer 230. The second interconnection electrically connects the second end of the capacitor Ceq to the edge pad 250.

The edge pad 250 is disposed on the second interconnection layer 230 to be electrically connected to the center pad 211. The edge pad 250 may be electrically connected to a contact pad 241 of the PCB 240 through a bonding wire 260.

The memory chip 210 is mounted on the PCB 240. A plurality of interconnections may be disposed in the PCB 240 to be electrically connected to an external device (not show) (e.g., SoC). The PCB 240 may receive a signal from the memory chip 210 through the contact pad 241 or transmit a signal to the memory chip 210. The PCB 240 may supply power to the memory chip 210 through the contact pad 241.

According to the above-described semiconductor device 200, a capacitor may be connected in parallel to a signal transmission line of the memory chip 210 to equalize a transmission signal. For example, a signal transmitted through the center pad 211 of the memory chip 210 and a signal transmitted through the edge pad 250 may be maintained nearly at the same voltage level. In example embodiments, for example, a capacitor Ceq is embedded to be disposed in the first interconnection layer 220 or the second interconnection layer 230. As a result, the signal integrity of a transmission signal may be improved by the capacitor Ceq connected in parallel to a signal transmission line. In one embodiment, the semiconductor device 200 may be included in a semiconductor package.

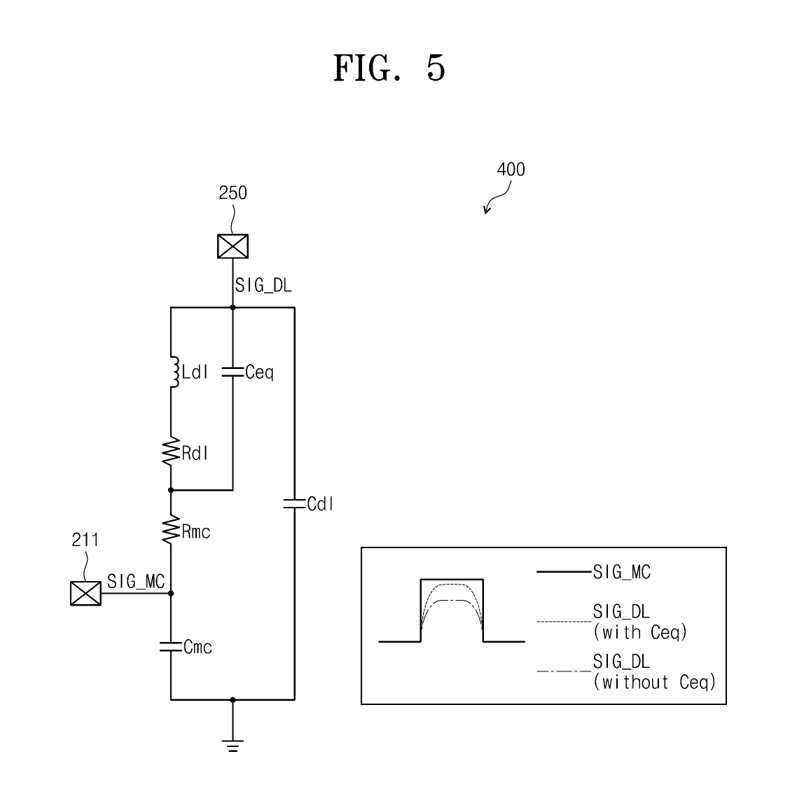

FIG. 5 is an equivalent circuit diagram of a memory chip and interconnection layers of the semiconductor device in FIG. 4 according to example embodiments. Specifically, an equivalent circuit diagram according to FIG. 5 shows an equivalent circuit 400 between a center pad 211 of a memory chip 210 and an edge pad 250.

The equivalent circuit 400 includes a chip resistor Rmc to equalize a resistance element of the memory chip 210, a chip capacitor Cmc to equalize a capacitance element of the memory chip 210, an interconnection resistor Rdl to equalize a resistance element of an interconnection, an interconnection inductor Ldl to equalize an inductance element of an interconnection, and an interconnection capacitor Cdl to equalize a capacitance element of an interconnection. The equivalent circuit 400 further includes a capacitor Ceq having a first end connected to the chip resistor Rmc and the interconnection resistor Rdl and a second end connected to the edge pad 250.

Variation of output signals depending on the capacitor Ceq will be described with reference to waveforms shown in FIG. 5.

A signal SIG_MC output from the center pad 211 of the memory chip 210 is shown as a solid line in the waveform diagram. For example, it is assumed that a waveform of a signal output from the center pad 211 is ideal.

When the capacitor Ceq does not exist, a voltage level of the signal SIG_DL output to the edge pad 250 may decrease as compared to a signal SIG_MC output from the memory chip 210 due to various impedance elements on a signal transmission line. If the signal is a data signal, an external device may read data output from the memory chip 210 as different data. That is, reliability of the signal may be degraded. In particular, in case of a low-power DRAM (LPDRAM) for use in a mobile device or the like, an impedance element on a transmission path has a great effect on a transmission signal due to limited use of power. Accordingly, equalizing between an output signal of the memory chip 210 and a signal output through the edge pad 250 is important to improve signal integrity. Thus, the semiconductor device 200 may include the capacitor Ceq in parallel to the signal transmission line to equalize a signal output to the edge pad 250 according to migration of a resonant frequency depending on the addition of the capacitor Ceq and charge and discharge operations of a capacitor.

When the capacitor Ceq exists, the voltage level of the signal SIG_DL output to the edge pad 250 increases according to the above-described capacitor operation as compared to a case where the capacitor Ceq does not exist. Moreover, the addition of the capacitor Ceq makes a slew rate of the signal SIG_DL output to the edge pad 250 higher than that in the case where the capacitor Ceq does not exist.

As described above, the signal SIG_DL output through the edge pad 250 may be equalized with the signal SIG_MC output from the memory chip 210 in the memory chip 210 by the addition of the capacitor Ceq embedded in the first interconnection layer 220 or the second interconnection layer 230. Thus, the signal integrity of a signal output from the memory chip 210 may be improved. In certain embodiments, the capacitor Ceq may be a capacitor component electrically connected between two portions of the second interconnection layer 230, and disposed on the second interconnection layer 230.

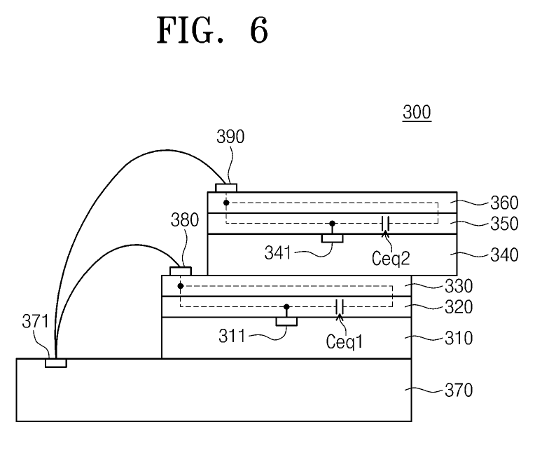

FIG. 6 is a cross-sectional view of a semiconductor device 300 according to example embodiments. As illustrated, the semiconductor device 300 includes a first memory chip 310, a first center pad 311, a first interconnection layer 320, a second interconnection layer 330, a first capacitor Ceq, a second memory chip 340, a second center pad 341, a third interconnection layer 350, a fourth interconnection layer 360, a printed circuit board (PCB) 370, a contact pad 371, a first edge pad 380, and a second edge pad 390. In one embodiment, the semiconductor device 300 may be included in a semiconductor package.

As compared to FIG. 4, in FIG. 6, an additional memory chip is further stacked on a memory chip. A structure of the second memory chip 340 staked on the first memory chip 310 may be substantially identical to that of the first memory chip 310. In addition, the structure of the first memory chip 310 may be substantially identical to that of the memory chip 210 in FIG. 4. Therefore, the same operations and structures as explained in FIGS. 4 and 6 will be omitted to avoid duplicate explanations.

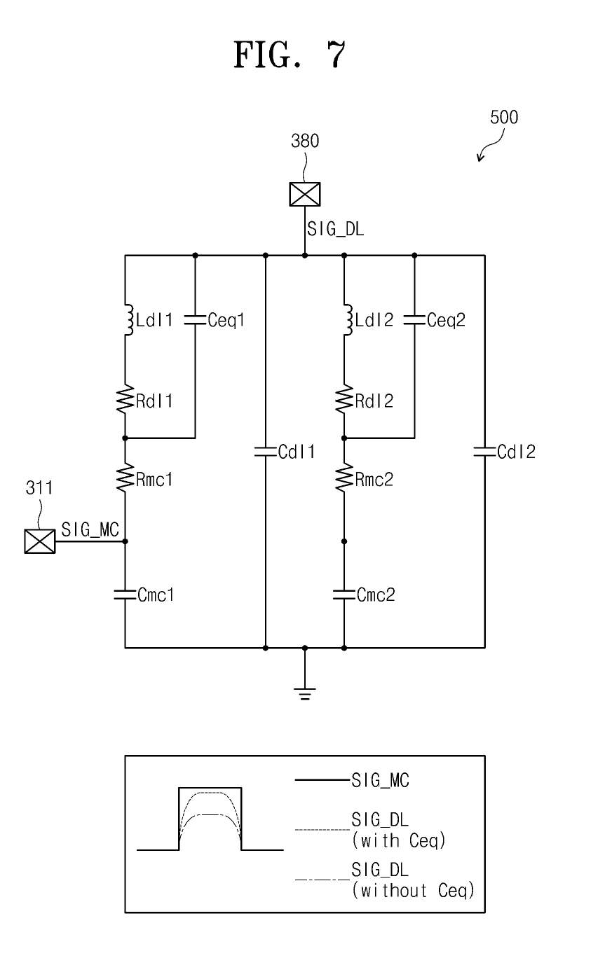

The first edge pad 380 and the second edge pad 390 are electrically connected to the same contact pad 371 of the PCB 370. For example, the first memory chip 310 and the second memory chip 340 cannot operate at the same time. Accordingly, when the first memory chip 310 operates, the second memory chip 340 connected through the same contact pad 371 and the third and fourth interconnection layers 350 and 360 act as a noise with respect to the first memory chip 310. Meanwhile, when the second memory chip 340 operates, the first memory chip 310 connected through the same contact pad 371 and the first and second interconnection layers 320 and 330 act as a noise with respect to the second memory chip 340. Accordingly, when memory chips are stacked, capacity may be higher than that in the same area but reliability of a signal may be degraded on the ground that edge pads of the respective memory chips are connected to the same contact pad of a printed circuit board (PCB). This will be described below in further detail with reference to FIG. 7.

FIG. 7 is an equivalent circuit diagram of a memory chip and interconnection layers of a semiconductor device in FIG. 6 according to example embodiments. Specifically, an equivalent circuit diagram according to FIG. 7 shows an equivalent circuit 500 between a center pad 311 of a first memory chip 310 and a first edge pad 380. That is, the equivalent circuit diagram is an equivalent circuit diagram of a memory chip and interconnections when the first memory chip 310 operates.

The equivalent circuit 500 includes first and second resistors Rmc1 and Rmc2 to equalize capacitance elements of the first memory chip 310 and a second memory chip 340, respectively and a first interconnection resistor Rdl1, a second interconnection inductor Ldl1, and a first interconnection capacitor Cdl1 to equalize a resistance element, an inductance element, and a capacitance element of the first interconnection 320 and a second interconnection layer 330, respectively. The equivalent circuit 500 further includes a first capacitor Ceq1 having a first end connected to the first chip resistor Rmc1 and the first interconnection resistor Rdl1 and a second end connected to the edge pad 380.

In addition, the equivalent circuit 500 includes first and second resistors Rmc1 and Rmc2 to equalize resistance elements of the first memory chip 310 and the second memory chip 340, respectively and first and second interconnection resistors Rdl1 and Rdl2, first and second interconnection inductors Ldl1 and Ldl2, and first and second interconnection capacitors Cdl1 and Cdl2 to equalize resistance elements, inductance elements, and capacitance elements of the first interconnection 320 and the second interconnection layer 330, respectively. In addition, the equivalent circuit 500 further includes the first capacitor Ceq1 having a first end connected to the first chip resistor Rmc1 and the first interconnection resistor Rdl1 and a second end connected to the first edge pad 380 and a second capacitor Ceq2 having a first end connected to the second chip resistor Rmc2 and the second interconnection resistor Rdl2 and a second end connected to the second edge pad 390.

Variation of output signals depending on the capacitor Ceq1 will be described with reference to waveforms shown in the right of FIG. 7.

A signal SIG_MC output from the center pad 311 of the memory chip 310 is shown as a solid line in the waveform diagram. For example, it is assumed that a waveform of a signal output from the center pad 311 is ideal.

When the capacitor Ceq1 does not exist, a voltage level of the signal SIG_DL output to the edge pad 380 may decrease as compared to a signal SIG_MC output from the first memory chip 310 due to various impedance elements on a signal transmission line. As compared to the case of FIG. 5, the voltage level of the signal SIG_DL output to the first edge pad 380 may further decrease due to an additional influence of the second memory chip 340 and the third and fourth interconnection layers 350 and 360. That is, the second memory chip 340 and the fourth and fourth interconnection layers 350 and 360 may act as a noise with respect to a transmission signal.

Accordingly, when the signal is a data signal, an external device may read data output from the first memory chip 310 as different data. That is, reliability of the signal may be degraded. In particular, in case of a low-power DRAM (LPDRAM) for use in a mobile device or the like, an impedance element on a transmission path has a great effect on a transmission signal due to limited use of power. Accordingly, equalizing between an output signal of the first memory chip 310 and a signal output through the edge pad 380 is important to improve signal integrity. Thus, the semiconductor device 300 may include the first and second capacitors Ceq1 and Ceq2 in parallel to the signal transmission line to equalize a signal output to the edge pad 380 according to migration of a resonant frequency depending on the addition of the first and second capacitors Ceq1 and Ceq2 and charge and discharge operations of a capacitor.

When the first capacitor Ceq1 exists, the voltage level of the signal SIG_DL output to the first edge pad 380 increases according to the above-described capacitor operation as compared to a case where the first capacitor Ceq1 does not exist. Moreover, the addition of the first capacitor Ceq1 makes a slew rate of the signal SIG_DL output to the first edge pad 380 higher than that in the case where the first capacitor Ceq1 does not exist.

Although a case where the first memory chip 310 operates is described in FIG. 7, the second capacitor Ceq2 may play the same role as the first capacitor Ceq1 when the second memory chip 340 operates.

As described above, a signal output through the first edge pad 380 or the second edge pad 390 may be equalized with a signal output from the first memory chip 310 or the second memory chip 340 due to the capacitor Ceq1 embedded in the first interconnection layer 320 or the second interconnection layer 330, and the second capacitor Ceq2 embedded in the third interconnection layer 350 or the fourth interconnection layer 360. In certain embodiments, each of the capacitors Ceq1 and Ceq2 may be a capacitor component electrically connected between two portions of the second interconnection layer 330 and connected between two portions of the fourth interconnection layer 360, and disposed on the second interconnection layer 330 and the fourth interconnection layer 360, respectively. Thus, signal integrity of a signal output from a memory chip may be improved.

As described herein, a capacitor is connected in parallel to a signal transmission line of a memory chip to improve signal integrity of signals transmitted from the memory chip or signals transmitted to the memory chip.

The above-disclosed subject matter is to be considered illustrative, and not restrictive, and the appended claims are intended to cover all such modifications, enhancements, and other features, which fall within the true spirit and scope of inventive concepts. Thus, to the maximum extent allowed by law, the scope of inventive concepts is to be determined by the broadest permissible interpretation of the following claims and their equivalents, and shall not be restricted or limited by the foregoing detailed description. While some example embodiments have been particularly shown and described, it will be understood by one of ordinary skill in the art that variations in form and detail may be made therein without departing from the spirit and scope of the claims.

1. A semiconductor device comprising:
a first set of pads disposed at a first vertical level on a substrate;
a first interconnection layer formed at a second vertical level higher than the first vertical level on the substrate, the first interconnection layer including a first set of interconnections;
a second interconnection layer formed at a third vertical level higher than the second vertical level on the substrate, the second interconnection layer including a second set of interconnections;
capacitive elements included in either the first or the second interconnection layer; and
a second set of pads disposed at a fourth vertical level higher than the third vertical level on the substrate,
wherein a first interconnection of the first set of interconnections and a second interconnection of the second set of interconnections are electrically connected to a first pad of the first set of pads and a second pad of the second set of pads, and
wherein a first capacitive element of the capacitive elements is connected between a first portion and a second portion of the first interconnection, or
wherein a first capacitive element of the capacitive elements is connected between a first portion and a second portion of the second interconnection.

2. The semiconductor device of claim 1, wherein each of the capacitive elements includes a dielectric material having a high-k constant.

3. The semiconductor device of claim 1, wherein the first set of pads connected to the capacitive elements are pads to which transmission signals are transmitted.

4. The semiconductor device of claim 1, wherein the first set of pads are disposed in a first direction at a central portion of the top surface of the substrate, and
wherein the second set of pads are disposed in a second direction at a first edge portion of the top surface of the substrate.

5. The semiconductor device of claim 4, wherein the capacitive elements are disposed at a second edge portion of the top surface of the substrate opposite to the first edge portion.

6. The semiconductor device of claim 1, wherein the substrate is included in a memory chip, and the semiconductor device further comprises:
a printed circuit board mounted on a bottom of the memory chip, the printed circuit board having a top surface at which a third set of pads are disposed,
wherein each pad of the second set of pads and a corresponding pad of the third set of pads are electrically connected through a bonding wire.

7. The semiconductor device of claim 1, further comprising:
a first via electrically connected between the first pad and the first interconnection; a second via electrically connected between the first interconnection and the second interconnection; and
a third via electrically connected the second interconnection and the second pad.

8. The semiconductor device of claim 7, further comprising:
a fourth via electrically connected between the first capacitive element and the second interconnection.

9. The semiconductor device of claim 1, when each of the first and second interconnection layers is a redistribution conductive layer.

10. A semiconductor device comprising:
a substrate;
a first set of pads disposed at a central portion of the substrate, the first set of pads arranged in a first direction or a second direction perpendicular to the first direction;
a second set of pads disposed at a first edge portion of the substrate, the second set of pads arranged in the first direction or the second direction;
a first interconnection layer formed at a first vertical level on the substrate, the first interconnection layer in which includes a first set of interconnections each electrically connected to a corresponding pad of the first set of pads;
a second interconnection layer formed at a second vertical level higher than the first vertical level on the substrate, the second interconnection layer including a second set of interconnections each electrically connected between a corresponding interconnection of the first set of interconnections and a corresponding pad of the second set of pads; and
capacitors included in either the first interconnection layer or the second interconnection layer,
wherein the capacitors are connected between a first portion of each interconnection of the first set of interconnections and a second portion of each interconnection of the first set of interconnections, respectively, or
wherein the capacitors are connected between a first portion of each interconnection of the second set of interconnections and a second portion of each interconnection of the second set of interconnections, respectively.

11. The semiconductor device of claim 10, wherein the substrate is included in a memory chip, and
wherein each of the capacitors is connected to a corresponding interconnection, which is a signal transmission line through which a signal of the memory chip is transmitted.

12. The semiconductor device of claim 10, further comprising:
a first via electrically connected between a first interconnection of the first set of interconnections and a first pad of the first set of pads;
a second via electrically connected between the first interconnection of the first set of interconnections and a second interconnection of the second set of interconnections; and
a third via electrically connected between the second interconnection of the second set of interconnections and a second pad of the second set of pads.

13. The semiconductor device of claim 12, further comprising:
a fourth via electrically connected between a first capacitor of the capacitors and the second portion of the second set of interconnections.

14. The semiconductor device of claim 10, wherein the capacitors are disposed in a second edge portion of the substrate opposite to the first edge portion when the capacitors are included in the first interconnection layer.

15. The semiconductor device of claim 11, wherein each of the first and second interconnection layers is a redistribution conductive layer.

16. A semiconductor device comprising:
a substrate;
first through third vias;
a first pad disposed at a first vertical level at a central portion of the substrate;
a first interconnection layer formed at a second vertical level higher than the first vertical level on the substrate, and electrically connected to the first pad through the first via;
a second interconnection layer formed at a third vertical level higher than the second vertical level on the substrate, and electrically connected to the first interconnection layer through the second via;
a second pad disposed at a fourth vertical level higher than the third vertical level on the substrate at a first edge portion of the substrate, and electrically connected to the second interconnection layer through the third via; and
a capacitive element electrically connected between a first portion and a second portion of the first interconnection layer at a second edge portion of the substrate opposite to the first edge portion, or
a capacitive element electrically connected between a first portion and a second portion of the second interconnection layer.

17. The semiconductor device of claim 16, further comprising:
an insulating layer directly connected to the second interconnection layer; and
a fourth via penetrating the insulating layer, and electrically connected between the second interconnection layer and the capacitive element.

18. The semiconductor device of claim 17, wherein the capacitive element is disposed on the insulating layer.

19. The semiconductor device of claim 16, further comprising:
a first insulating layer between the first and second interconnection layers,
wherein the first insulating layer includes a first dielectric material having a first dielectric constant, and
wherein the capacitive element includes a second dielectric material having a second dielectric constant higher than the first dielectric constant.

20. The semiconductor device of claim 16, wherein the capacitive elements are disposed at a second edge portion of the top surface of the substrate opposite to the first edge portion.
